(19) United States
(12) Patent Application Publication
(10) Pub. No.: US 2025/0309121 A1
(43) Pub. Date: Oct. 2, 2025

(54) BACKSIDE POWER DELIVERY TO LOGIC OF A MEMORY ARCHITECTURE

(71) Applicant: Micron Technology, Inc., Boise, ID (US)

(72) Inventors: Bharat Bhushan, Boise, ID (US); Kunal R. Parekh, Boise, ID (US); Amy Rae Griffin, Boise, ID (US); Akshay N. Singh, Boise, ID (US)

(21) Appl. No.: 19/090,125

(22) Filed: Mar. 25, 2025

Related U.S. Application Data
(60) Provisional application No. 63/572,863, filed on Apr. 1, 2024.

(51) Int. Cl. H01L 23/538; H01L 21/66; H01L 21/683; H01L 21/768; H01L 23/498; H01L 25/18; H10B 80/00; H10D 80/30

(52) U.S. Cl. CPC H01L 23/5384; H01L 21/6836; H01L 21/76877; H01L 22/30; H01L 23/49816; H01L 25/18; H10B 80/00; H10D 80/30; H01L 2225/06541

(57) ABSTRACT

Methods, systems, and devices for backside power delivery to logic of a memory architecture are described. A semiconductor system may implement logic chips stacked above stacks of memory chips, where the stacks of memory chips are positioned above circuitry associated with providing power to the semiconductor system. The semiconductor system may include a dielectric layer above the logic chips including conductive channels. For example, the circuitry may deliver power to the logic chips based on transferring power along power delivery vias to the conductive channels which may provide the power to the logic chips. In some examples, a front side of the logic chips may be bonded with a backside of the stacks of memory chips, and a backside of the logic chips may be bonded with the conductive channels, such that power is delivered to the backside of the logic chips.

### CROSS REFERENCE

The present Application for Patent claims priority to U.S. Patent Application No. 63/572,863 by Bhushan et al., entitled “BACKSIDE POWER DELIVERY TO LOGIC OF A MEMORY ARCHITECTURE,” filed Apr. 1, 2024, which is assigned to the assignee hereof, and which is expressly incorporated by reference in its entirety herein.

### TECHNICAL FIELD

The following relates to one or more semiconductor systems, including backside power delivery to logic of a memory architecture.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports backside power delivery to logic of a memory architecture in accordance with examples as disclosed herein.

FIG. 2 shows an example of a system that supports backside power delivery to logic of a memory architecture in accordance with examples as disclosed herein.

FIG. 3 shows an example of a memory architecture that supports backside power delivery to logic of a memory architecture in accordance with examples as disclosed herein.

FIGS. 4A, 4B, 4C, 4D, 4E, 4F, 4G, and 4H show examples of processing steps that supports backside power delivery to logic of a memory architecture in accordance with examples as disclosed herein.

FIGS. 5 through 7 show flowcharts illustrating a method or methods that support backside power delivery to logic of a memory architecture in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as central processing units (CPUs) or graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some semiconductor systems, one or more stacks of memory chips (e.g., relatively smaller dies) may be stacked above one or more logic chips (e.g., logic chiplets). In some such cases, the one or more logic chips may be positioned above (e.g., contacting) a substrate including circuitry associated with providing power to the semiconductor systems. For example, power may be provided to the one or more logic chips, which may include conductive channels (e.g., vias) for transmitting a portion of the power to the one or more stacks of memory chips above the one or more logic chips. However, operating the one or more logic chips and providing power to the one or more logic chips may result in relatively high thermal concentration at the one or more logic chips. Thus, implementing the one or more logic chips directly coupled with (e.g., contacting) the circuitry associated with providing power to the semiconductor system may further increase thermal concentration at the one or more logic chips, which may cause degradation to the one or more logic chips, thereby affecting latency of the semiconductor system, among other disadvantages.

Further, in some semiconductor systems, the one or more logic chips may be formed from a logic wafer including multiple logic chips, such that the one or more logic chips may be diced and selected for use in the semiconductor systems. However, in some cases when forming the logic wafer, a quantity of the logic chips may be at least partially defective. Implementing the defective logic chips within the semiconductor systems may cause deficiencies in the semiconductor system, resulting in portions of the semiconductor system being defective.

In accordance with examples as described herein, a semiconductor system may implement one or more logic chips stacked above one or more stacks of memory chips, where the one or more stacks of memory chips are positioned above (e.g., contacting) a substrate including circuitry associated with providing power to the semiconductor system. The semiconductor system may include a dielectric silicon layer above the one or more logic chips including conductive channels (e.g., redistribution layers) which may be coupled with the one or more logic chips and the circuitry associated with providing power. For example, the circuitry may deliver power to the one or more logic chips based on transferring power along one or more power delivery vias to the conductive channels which may provide the power to the one or more logic chips. In some examples, the one or more logic chips may be formed above the one or more stacks of memory chips based on bonding a front side of the one or more logic chips with a backside of the one or more stacks of memory chips, and bonding a backside of the one or more logic chips with the conductive channels, such that power is delivered to the backside of the one or more logic chips. Implementing the one or more logic chips above the one or more stacks of memory chips may alleviate thermal concentration concerns during power delivery by increasing thermal distribution throughout the semiconductor system. In some cases, with relatively greater thermal distribution, the semiconductor system may experience less degradation, resulting in improved latency of the semiconductor system, among other advantages.

Further, during forming the semiconductor system, each logic chip may be tested for defects prior to implementing the respective logic chip in the semiconductor system. For example, each logic chip of a wafer may be tested to determine whether the respective logic chip is defective. Then, the logic chips that are determined not to be defective are selected for use in the semiconductor system. Implementing verified operable logic chips in the semiconductor system may further increase reliability of the semiconductor system and/or increase yield of a process to create the semiconductor systems, among other advantages.

In addition to applicability in memory systems as described herein, techniques for backside power delivery to logic of a memory architecture may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing degradation of semiconductor components throughout the life of a semiconductor system, which may extend the life of electronic devices and thereby reducing electronic waste, among other benefits.

Features of the disclosure are illustrated and described in the context of systems and architectures. Features of the disclosure are further illustrated and described in the context of memory architectures, processing steps, and flowcharts.

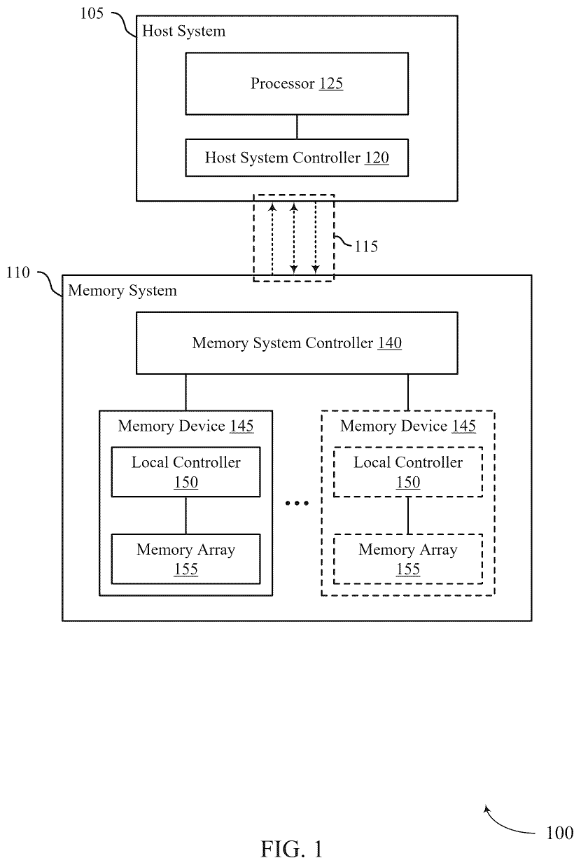

FIG. 1 shows an example of a system 100 that supports backside power delivery to logic of a memory architecture in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked die architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

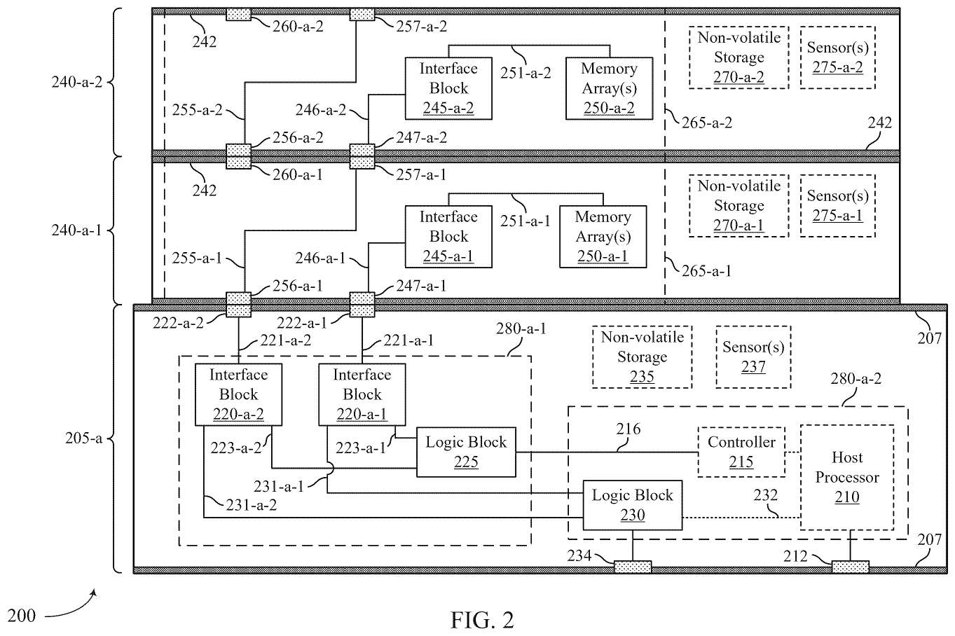

FIG. 2 shows an example of a system 200 (e.g., a semiconductor system, a system of coupled semiconductor dies, an HBM system, a 3D stacked memory system) that supports backside power delivery to logic of a memory architecture in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth memory configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220. The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 (e.g., via a bus, via a contact 212 for a host processor 210 external to a die 205) such that the logic block 230 may support an interface between the host processor 210 and the logic blocks 225 or interface blocks 220. For example, a host processor 210 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210. Additionally, or alternatively, a logic block 230 may communicate with a host processor 210, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). A hybrid bond may be an example of a permanent bond that combines a dielectric bond (SiOx) with embedded metal (Cu) to form interconnections. Hybrid bonding may enable smaller bonding pitches, higher memory cell density, improved signaling over conductive lines, improved power distribution, among other benefits. In an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In accordance with examples as described herein, the system 200 may implement the die 205 stacked above the dies 240 (e.g., die 240-a and die 240-b), where the dies 240 are positioned above (e.g., contacting) a substrate including circuitry associated with providing power to the system 200. The system 200 may include a dielectric silicon layer above the die 205, including conductive channels (e.g., redistribution layers) which may be coupled with the die 205 and the circuitry associated with providing power. For example, the circuitry may deliver power to the die 205 based on transferring power along one or more power delivery vias to the conductive channels which may provide the power to the die 205. In some examples, the die 205 may be formed above the dies 240 based on bonding a front side of the die 205 with a backside of the die 240-a or the die 240-b (e.g., whichever die 240 is the top die), and bonding a backside of the die 205 with the conductive channels, such that power is delivered to the backside of the die 205. Implementing the die 240 above the dies 240 may alleviate thermal concentration concerns during power delivery by increasing thermal distribution throughout the system 200. In some cases, with relatively greater thermal distribution, the system 200 may experience less degradation, resulting in improved latency of the system 200, among other advantages.

Further, during forming the system 200, a die 205 (e.g., and the dies 240) may be tested for defects prior to implementing the die 205 in the system 200. For example, the die 205 may be tested to determine whether the die 205 is defective, and after determining the die 205 is not defective, the die 205 may be selected for use in the system 200. Implementing verified operable components in the system 200 may further increase reliability of the system 200, among other advantages.

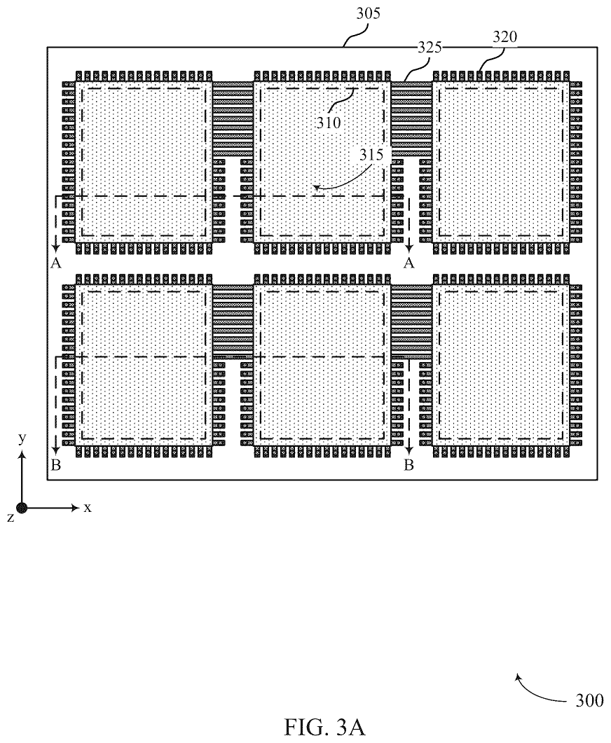

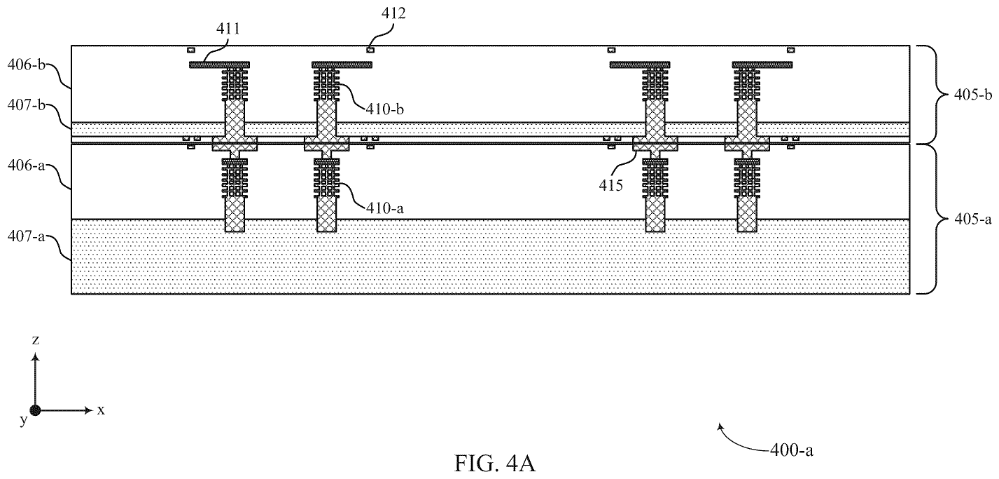

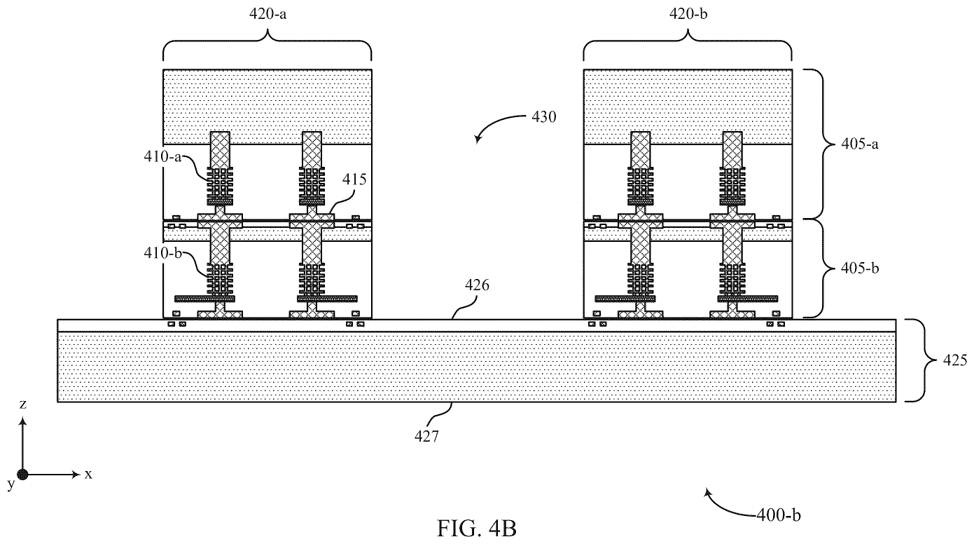

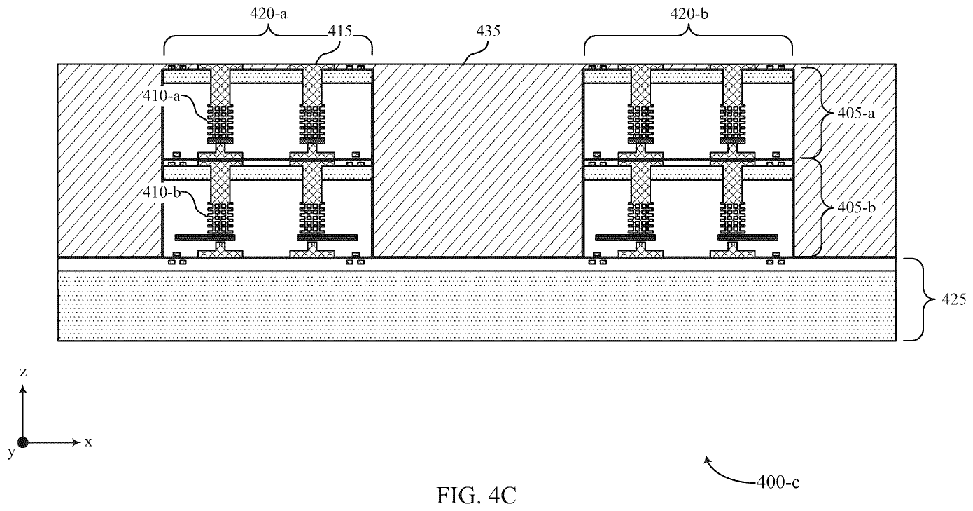

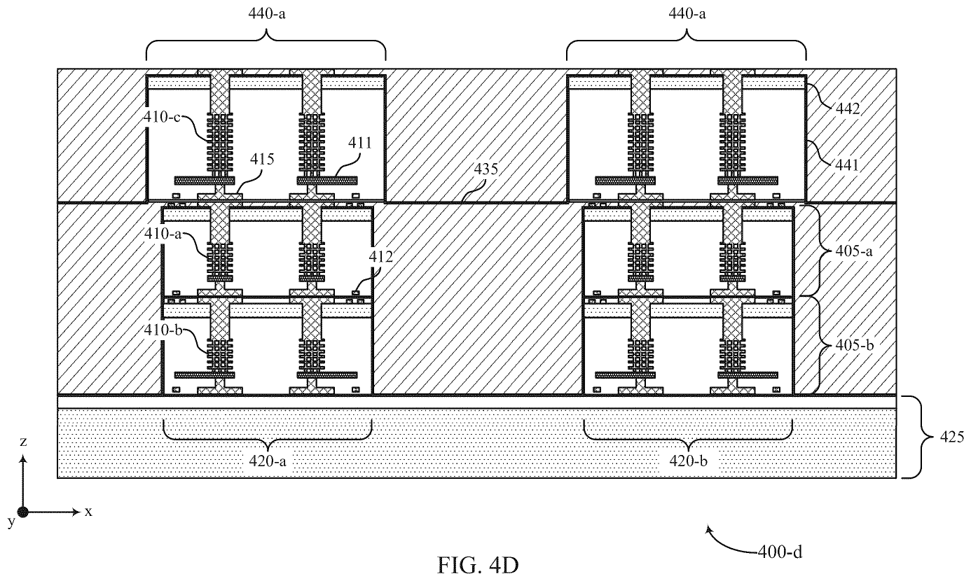

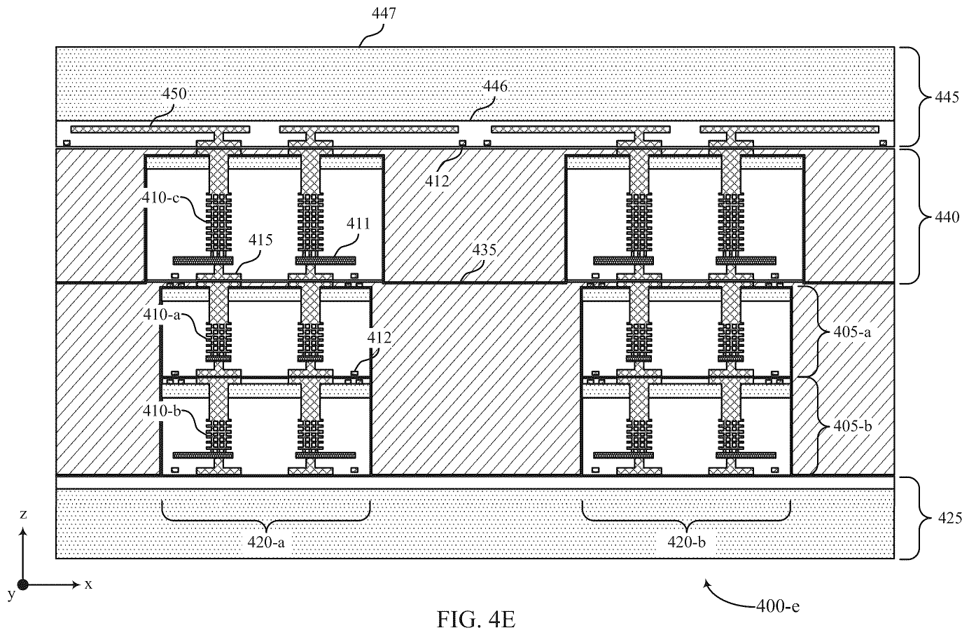

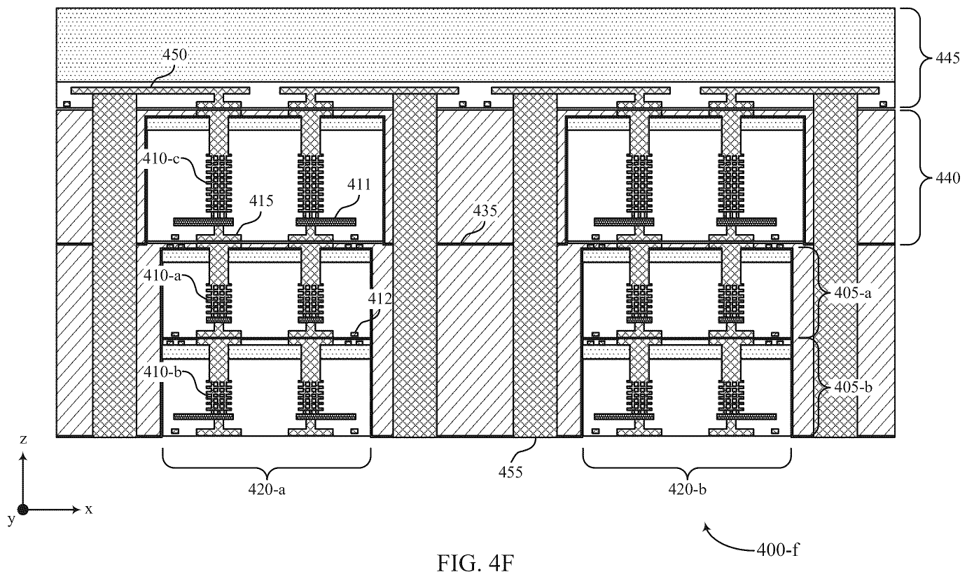

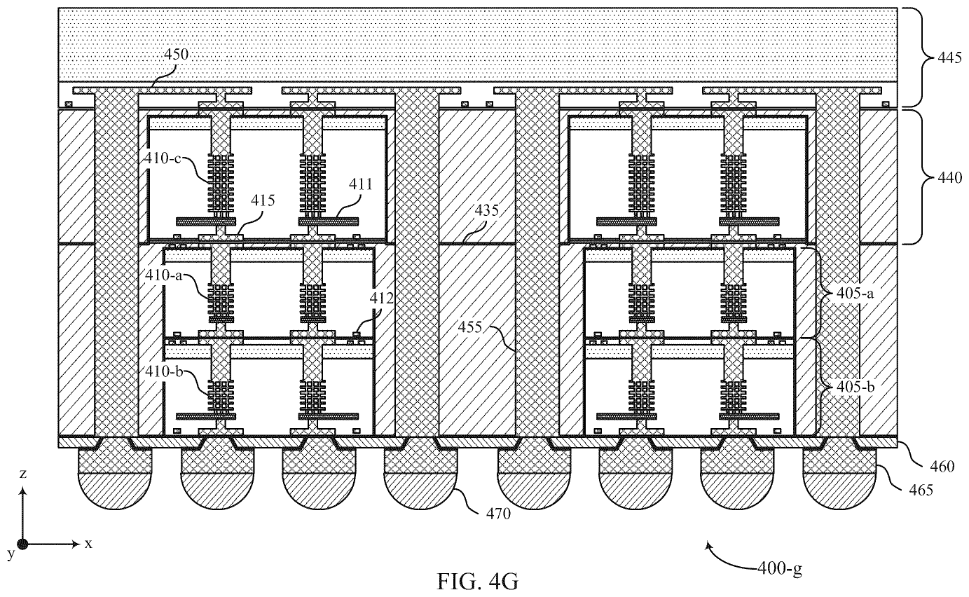

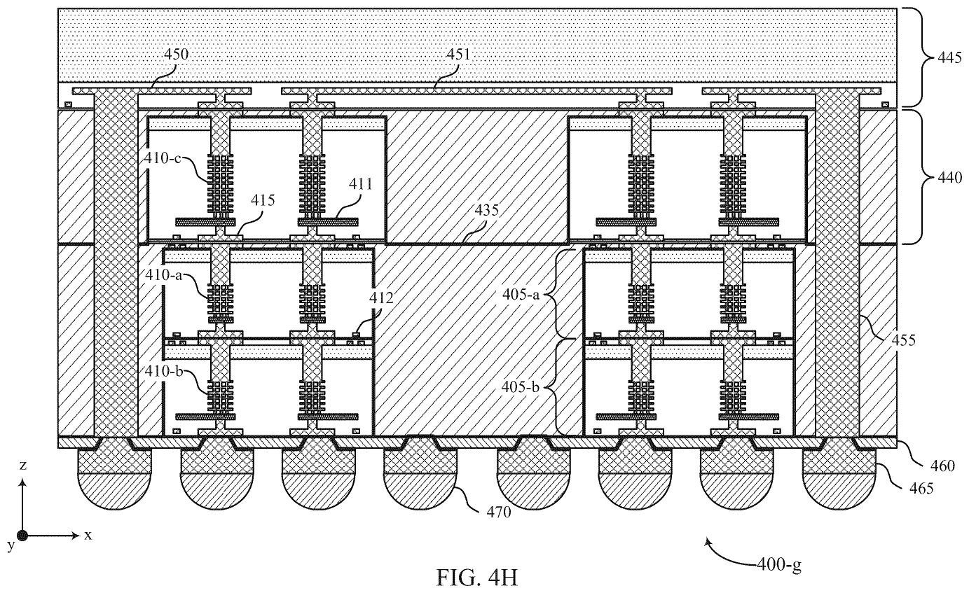

FIG. 3 shows an example of a memory architecture 300 that supports backside power delivery to logic of a memory architecture in accordance with examples as disclosed herein. The memory architecture 300 may implement aspects of, or be implemented by, a system, which may be an example of a system 100 or a system 200, as described with reference to FIGS. 1 and 2, respectively. For example, the memory architecture 300 may include chips, which may be examples of a die 205 or a die 240 (e.g., a die 240-a, a die 240-b). For illustrative purposes, aspects of the memory architecture 300 may be described with reference to an x-direction, a y-direction, and a z-direction of the illustrated coordinate systems. For example, FIG. 3 illustrates the memory architecture 300 from a bottom view in an xy-plane. Additionally, FIG. 3 illustrates a cross-sectional line A-A and a cross sectional line B-B for illustrating cross-sectional views of a memory architecture as shown in FIGS. 4A through 4H. The memory architecture 300 illustrates a memory architecture resulting from the processing steps 400, as described with reference to FIGS. 4A through 4H.

The memory architecture 300 may include a dielectric silicon layer 305 configured to support redistribution layers for transferring power and/or signaling to the dies (e.g., dies 205, dies 240) of the memory architecture 300. The memory architecture may include a quantity of chips (e.g., logic chips, volatile memory chips) disposed (e.g., formed, deposited, mounted) below the dielectric silicon layer 305, where each chip may be a die, such as a die 205 or a die 240 (e.g., a die 240-a, a die 240-b). In some cases, each chip may be a relatively smaller die formed (e.g., diced, separated) from a relatively larger die, which may be an example of a wafer (e.g., a semiconductor wafer). In some examples, each chip may be referred to as a chiplet based on each chip being a portion of the relatively larger die or wafer. In some case, the memory architecture 300 may include a substrate, which may be a semiconductor material (e.g., a surface) in an xy-plane upon which other components may be formed. In some cases, the memory architecture 300 may include a polyimide layer at a front side of the dies.

The memory architecture 300 may include a quantity of memory stacks 310 (e.g., volatile memory stacks). The memory stacks 310 may be DRAM (e.g., 3D stacked memory) memory stacks each including a quantity memory chips (e.g., volatile memory chips), which may be DRAM (e.g., 3D stacked memory) memory chips or DRAM memory dies, such as the dies 240 (e.g., die 240-a, die 240-b). For example, the memory architecture 300 illustrates six memory stacks, where each memory stack includes one or more memory chips (e.g., two memory chips). The memory chips of each memory stack may be stacked such that the memory chips are bonded together to form the memory stack. In some cases, the memory chips may be hybrid bonded such that conductive (e.g., metal) materials of the memory chips may be bonded together (e.g., and dielectric material of the memory chips may be bonded together). In some examples, these memory chips may be hybrid bonded through wafer-on-wafer integration flows. In other examples, these memory chips may be hybrid bonded through chip-on-wafer integration flows, or stack-on-wafer integration flows. In some cases, each memory chip may include one or more memory arrays and supporting circuitry (e.g., CMOS circuitry), which may include one or more controllers, one or more processors, one or more interfaces, and/or processing circuitry. The one or more memory arrays may be volatile memory arrays (e.g., DRAM arrays) including a quantity of volatile memory cells (e.g., DRAM cells).

The memory architecture 300 may include a quantity of logic chips 315 disposed below the dielectric silicon layer and above the quantity of memory stack 310. For example, each logic chip 315 may be stacked with a respective memory stack 310. In some examples, the logic chips 315 may be bonded with the memory stacks 310, such that each logic chip 315 may be hybrid bonded with a respective memory stack 310 (e.g., a memory chip of the memory stack 310). In some examples, the logic chips 315 may be examples of host systems such as graphics processing units and may include one or more controllers, one or more processors, one or more interfaces, and/or processing circuitry associated with supporting operations of the memory stacks 310, such as the die 205. In some examples, the logic chips 315 may be examples of interface blocks (e.g., memory interface blocks), as described with reference to FIG. 2. The interface block may be positioned between the memory stack and the host system. The logic chips 315 may be configured to facilitate performing operations on the memory stacks 310, such as receiving access commands from a host system and performing corresponding access operations on the memory stacks 310. In some cases, each logic chip 315 may include one or more memory arrays (e.g., volatile memory arrays, cache memory, buffer, non-volatile memory arrays) and supporting circuitry (e.g., CMOS circuitry).

In some cases, the logic chips 315 may be hybrid bonded to memory stack 310 such that conductive (e.g., metal) materials of the memory stack 310 and logic chip 315 may be bonded together (e.g., and dielectric material of the memory stack 310 and logic chip 315 may be bonded together). In some examples, the hybrid bonding may implement wafer-on-wafer integration flows. In other examples, the hybrid bonding may implement chip-on-wafer integration flows, or stack-on-wafer integration flows. In some cases, the logic chips 315 may be similar sized to the memory stack 310, such that the logic chips 315 may have a similar area to the memory stack 310 in an xy-plane. In other cases, the logic chips 315 may be differently sized than the memory stack 310, such that the logic chips 315 may have a first area in an xy-plane and the memory stack 310 may have a second area in an xy-plane. In some examples, the logic chips 315 may be similar sized to one another, whereas in other examples, the logic chips 315 may be differently sized based on components included within the logic chips 315.

The memory chips and the logic chips 315 may include internal vias (e.g., not illustrated for clarity), such as through-silicon vias (TSVs), which may be conductive channels extending through the respective chips. For example, each memory chip and each logic chip 315 may include one or more internal vias for transferring power and/or signaling through the respective chip to another chip or component. The internal vias of the memory chips and the logic chips 315 may be bonded together, such that the conductive channels may extend through the logic chips 315 and the memory chips. In some examples, the conductive channels may be configured to transfer power from the logic chips 315 to the memory chips of the corresponding memory stack 310.

The memory chips and the logic chips 315 may each include a quantity of signal paths extending through the respective chips. In some such cases, the memory chips and the logic chips 315 may support shared connections and/or waterfall (e.g., cascading) connections for transmitting signaling between the memory chips and the logic chips 315. For example, each memory stack 310 may include a quantity of signal paths connected to the respective logic chip 315, where the signal paths are configured to support a relatively high quantity of signals being transmitted between the memory chips of the memory stack 310 and the logic chip 315.

The dielectric silicon layer 305 may be disposed above the quantity of logic chips 315. The dielectric silicon layer 305 may be configured to support redistribution layers 325 configured for transferring power and/or signaling to the logic chips 315. The redistribution layers 325 may be conductive channels formed within the dielectric silicon layer and extending to the logic chips 315. In some cases, the redistribution layers 325 may extend along the x-direction between adjacent logic chips 315 (e.g., in the x-direction). For example, the redistribution layers 325 may extend from an internal via of a logic chip 315 to an internal via of another logic chip 315 adjacent to the logic chip 315. In other cases, the redistribution layers 325 may extend between the internal vias of the logic chips 315 and vias 320. In some examples, due to varying sizes of the logic chips 315, the memory architecture 300 may include additional redistribution layers 325 in between logic chips 315 and a memory stack 310. In some cases, the redistribution layers 325 may be configured to transmit relatively high speed signaling between the logic chips 315.

The memory architecture 300 may include the vias 320 extendingto the redistribution layers 325. The vias 320 may be through-dielectric vias (TDVs), which may be conductive channels extending through dielectric material (e.g., not shown for clarity) surrounding the memory stacks 310 and the logic chips 315. In some cases, the vias 320 may include lengths extending from one of the surfaces of logic chips 315 to another (e.g., opposite) surface of the memory architecture 300. The vias 320 may be configured to transfer power through the memory architecture 300 (e.g., from a power source or power circuitry outside the memory architecture 300) to the redistribution layers 325, where the redistribution layers 325 may be configured to transfer the power to the logic chips 315. After receiving the power from the redistribution layers 325, the logic chips 315 may transfer the power to the corresponding memory stacks along the internal vias. In some cases, the vias 320 may surround each logic chip 315 and be spaced along the edges of the logic chips 315. In some cases, the vias 320 may not be present in regions associated with the redistribution layers 325 extending between adjacent logic chips 315.

In some cases, processing steps for forming the memory architecture 300 may include testing operations. In some such cases, the processing steps may include testing each chip to determine whether each chip is defective prior to implementing each chip in the memory architecture 300. For example, the wafer associated with the quantity of logic chips 315 may be tested to determine whether each logic chip 315 is at least partially defective. Likewise, the memory chips may be tested to determine whether each memory chip is at least partially defective. In some cases, some chips may be determined as defective chips, whereas other chips may be verified as operable chips. In some such cases, the operable chips may be selected and implemented in the memory architecture 300, and the defective chips may not be implemented (e.g., discarded) in the memory architecture 300. In some examples, testing and selecting the verified operable chips may be performed prior to dicing the wafer to form the chips. However, in other examples, testing and selecting the verified operable chips may be performed after dicing the wafer to form the chips. In some examples, “dice” or “dicing” may refer to a process in which one or more dies are separated from a wafer of multiples dies (e.g., via sawing, laser cutting, scribing, breaking, etching, or other separation technique) to form individual die chips.

In accordance with examples as described herein, implementing the logic chips 315 above the memory stacks may alleviate thermal concentration concerns during power delivery to the memory architecture 300, by increasing thermal distribution throughout the memory architecture 300. In some cases, with relatively greater thermal distribution, the memory architecture 300 may experience less degradation, resulting in improved latency of operating the memory architecture 300. Further, implementing processing steps for testing the chips prior to forming the memory architecture 300 may ensure defective chips are not implemented in the memory architecture. That is, implementing verified operable components in the memory architecture 300 may further increase reliability of the memory architecture 300, among other advantages.

FIGS. 4A through 4H show examples of processing steps 400 (e.g., processing step 400-a, processing step 400-b, processing step 400-c, processing step 400-d, processing step 400-e, processing step 400-f, processing step 400-g) that support backside power delivery to logic of a memory architecture in accordance with examples as disclosed herein. FIGS. 4A through 4G show cross-sectional views of the memory architecture at the cross-sectional line A-A illustrated in FIG. 3. FIG. 4H shows a cross-sectional view of the memory architecture at the cross-sectional line B-B illustrated in FIG. 3. The processing steps 400 may illustrate aspects of manufacturing operations for fabricating aspects of a memory architecture, which may be an example of a memory architecture 300, as described with reference to FIG. 3, or implemented by a system, which may be an example of a system 100 or a system 200, as described with reference to FIGS. 1 and 2, respectively. For example, performing the processing steps 400 as described herein may result in the memory architecture 300.

For illustrative purposes, aspects of the memory architecture may be described with reference to an x-direction, a y-direction, and a z-direction of the illustrated coordinate systems. In some cases, the memory architecture may be described relative to various cross-sectional views. For example, processing step 400-a illustrates the memory architecture from a cross-sectional view in an xz-plane, where the memory architecture extends a distance along the y-direction into the page. Although the processing steps 400 illustrate examples of relative dimensions and quantities of various features, aspects of the memory architecture may be implemented with other relative dimensions or quantities of such features in accordance with examples as disclosed herein. In the following description of the processing steps 400, some methods, techniques, processes, and operations may be performed in different orders or at different times. Further, some operations may be left out of the processing steps 400, or other operations may be added to the processing steps 400. The processing steps 400 may illustrate operations associated with forming the memory architecture in which logic chips are positioned above stacks of memory chips and deliver power through vias extending through the memory architecture.

Operations illustrated in and described with reference to FIGS. 4A through 4H may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 4A illustrates a first processing step 400-a for forming memory chips 405 (e.g., volatile memory chips). The processing step 400-a may include forming a memory chip 405-a and a memory chip 405-b, which may be examples of dies 240, as described with reference to FIG. 2. In some examples, each memory chip 405 may be a DRAM chip (e.g., a DRAM chiplet, a DRAM die) including one or more volatile memory arrays (e.g., DRAM arrays) of volatile memory cells (e.g., DRAM cells) and supporting circuitry (e.g., one or more controllers, one or more processors, processing circuitry). The memory chips 405 may be formed such that each memory chip 405 includes a core portion 406 for the volatile memory arrays and a dielectric portion 407.

Further, the memory chips 405 may be formed such that each memory chip 405 includes a quantity of vias 410, which may be conductive channels extending through the memory chips 405. In some implementations, the vias 410 may be through-silicon vias (TSVs), such that each via 410 extends through one or more silicon materials of the memory chips 405. In some examples, the vias 410 may be configured to transfer power and/or signaling between the memory chips 405 or other components of the memory architecture. Additionally, the memory chips 405 may be formed such that each memory chip 405 includes contacts 411 coupled with the vias 410 by conductive lines. The contacts 411 may support forming bonding pads 415 within the memory chips 405. For example, each memory chip 405 may include bonding pads 415 to support bonding the vias 410 of the memory chips 405. In some examples, each bonding pad 415 may include a quantity of conductive contacts and a quantity of dielectric contacts. Further, the memory chips 405 may be formed such that each memory chip 405 includes alignment features 412 to support aligning memory chips 405 for bonding the memory chips 405.

In some cases, forming the memory chips 405 may include forming a wafer of memory chips 405, and testing the memory chips 405 to determine whether each memory chip 405 is defective. The memory chips 405 determined to not be defected (e.g., verified as operable) may be selected for use in the memory architecture. In some cases, the memory chips 405 may be diced from the wafer to separate defective memory chips from operable memory chips. In some such cases, the operable memory chips may be bonded together into another wafer.

After forming each memory chip 405, the processing step 400-a may include bonding the memory chip 405-a and the memory chip 405-b. In some examples, bonding the memory chip 405-a and the memory chip 405-b may form the (e.g., another) wafer. In some cases, the memory chip 405-b may be initially positioned above the memory chip 405-a. In some such cases, the memory chip 405-b may be aligned with the memory chip 405-b using the alignment features 412 of each memory chip 405. In some examples, the alignment features 412 may be positioned within the memory chips 405 such that aligning the alignment features 412 along the x-direction and the y-direction may cause the vias 410 of the memory chips 405 to be aligned. For example, aligning the memory chips 405 may include aligning a via 410-b of the memory chip 405-b with a via 410-a of the memory chip 405-a. In some implementations, aligning the vias 410 of the memory chips 405 may align the bonding pads of the memory chips 405, such that a bonding pad 415 associated with the via 410-b may be aligned with a bonding pad 415 associated with the via 410-a. After aligning the memory chips 405, the memory chips 405 may be bonded together using hybrid bonding, such that a bonding pad 415 associated with the memory chip 405-b is hybrid bonded with a bonding pad 415 associated with the memory chip 405-a. In some cases, hybrid bonding the bonding pads 415 may include bonding the conductive contacts of one bonding pad 415 with the conductive contacts of another bonding pad 415 (e.g., and bonding the dielectric contacts of one bonding pad 415 with the dielectric contacts of the other bonding pad 415). In some examples, bonding the memory chips 405 may include bonding a front side (e.g., a top surface) of the memory chip 405-a with a back side (e.g., a bottom surface) of the memory chip 405-b. Bonding the memory chips 405 may form the basis for one or more stacks of memory chips 405.

FIG. 4B illustrates a second processing step 400-b for forming memory stacks 420 (e.g., volatile memory stacks). The processing step 400-b may include dicing the memory chips 405 to separate the memory chips 405 into memory stacks 420. For example, the processing step 400-b illustrates plasma dicing the memory chips 405 into a memory stack 420-a and a memory stack 420-b, where each memory stack 420 includes the memory chip 405-a and the memory chip 405-b. In some cases, dicing the memory chips 405 into the memory stacks 420 may include dicing a wafer including the memory chip 405-a and the memory chip 405-b. The memory chips 405 may be diced such that each memory stack 420 includes one or more vias extending through the memory stack 420. The one or more vias may extend through the memory stack 420 based on bonding the vias 410 of the memory chips 405, such that the vias extending through the memory stack 420 may be made from the vias 410-a and the vias 410-b. For example, the processing step 400-b illustrates the memory architecture where each memory stack 420 includes two vias extending through the memory stack 420.

The processing step 400-b also includes bonding the memory stacks 420 with a sacrificial layer 425. For example, the memory stacks 420 may be fusion bonded with the sacrificial layer 425 such that the dielectric contacts of the bonding pads 415 (e.g., or the contacts 411) associated with each memory stack 420 are bonded with dielectric contacts of the sacrificial layer 425. In some examples, the sacrificial layer 425 may be a silicon-based dielectric material. In some implementations, the sacrificial layer 425 may include a region 426 and a region 427, where the region 426 may include a quantity of dielectric films. In some cases, bonding the memory stacks 420 may include bonding a front side (e.g., a top surface) of the memory chip 405-b with a front side (e.g., a top surface) of the sacrificial layer 425, such that the memory stacks 420 may be flipped along the z-direction prior to bonding the memory stacks 420 with the sacrificial layer 425. In some such cases, bonding the memory stacks 420 with the sacrificial layer 425 may cause the backside of the memory chip 405-a to be exposed as a top surface of the memory architecture. Bonding the memory stacks 420 with the sacrificial layer 425 may form voids 430 between the memory stacks 420.

In some cases, the processing step 400-b may include dicing the wafer of memory chips 405 and testing the wafer of memory chips 405 to determine which memory chips 405 are operable. That is, operable memory chips 405 may be separated (e.g., diced) from wafer and assembled together to form the memory stacks 420. After assembling the memory stacks 420 using memory chips 405 verified as operable, the processing step 400-b may include bonding the memory stacks 420 with the sacrificial layer 425. Thus, the processing step 400-b may form a memory architecture with a relatively greater proportion of operable memory chips 405 than one or more originally formed wafers from which the memory chips 405 were diced. As such, the described examples provide for manufacturing procedures that are based on the bonding of multiple reconstructed wafers, which may increase a manufacturing yield (e.g., of the memory architecture 300).

FIG. 4C illustrates a third processing step 400-c for forming a dielectric material 435 in the voids 430. For example, the processing step 400-c may include depositing the dielectric material 435 on the front side of the sacrificial layer 425 such that the dielectric material 435 is disposed above the sacrificial layer 425 along the z-direction. In some cases, the dielectric material 435 may be a silicon oxide material. Further, depositing the dielectric material 435 in the voids 430 may fill the voids 430 with the dielectric material 435, such that the dielectric material 435 may surround the memory stacks 420. For example, the dielectric material 435 may be disposed between the memory stack 420-a and the memory stack 420-b. In some examples, the dielectric material 435 may be deposited to a height equivalent to a height of the memory stacks 420. In some examples, the processing step 400-c may include planarizing (e.g., remove a top portion, etching a thin layer of the memory architecture) the memory architecture such that the memory stacks 420 and the dielectric material 435 are coplanar. In some such examples, planarizing the memory architecture may expose the bonding pads 415 of the memory stacks 420.

FIG. 4D illustrates a fourth processing step 400-d for forming logic chips 440. The processing step 400-d may include forming a logic chip 440-a and a logic chip 440-b, which may be examples of dies 205, as described with reference to FIG. 2. In some examples, each logic chip 440 may include one or more controllers, one or more processors, and/or processing circuitry to support operations of the memory stacks 420. The logic chips 440 may be formed such that each logic chip 440 includes a core portion 441 and a dielectric portion 442. Further, the logic chips 440 may be formed such that each logic chip 440 includes the vias 410 extending through the logic chips 440. Additionally, the logic chips 440 may be formed such that each logic chip 440 includes contacts 411 coupled with the vias 410 by conductive lines. The contacts 411 may support forming bonding pads 415 within the logic chips 440. For example, each logic chip 440 may include bonding pads 415 to support bonding the vias 410 with the vias 410 of the memory chips 405. In some examples, each bonding pad 415 may include a quantity of conductive contacts and a quantity of dielectric contacts. Further, the logic chips 440 may be formed such that each logic chip 440 includes alignment features 412 to support aligning logic chips 440 for bonding the memory chips 405.

In some cases, forming the logic chips 440 may include forming a wafer of logic chips 440, and testing the logic chips 440 to determine whether each logic chip 440 is defective. The logic chips 440 determined to not be defected (e.g., verified as operable) may be selected for use in the memory architecture. In some cases, the logic chips 440 may be diced from the wafer to separate defective logic chips from operable logic chips. For example, the processing step 400-d may include dicing a wafer of the logic chips 440 and testing the wafer of logic chips 440 to determine which logic chips 440 are operable. That is, operable logic chips 440 may be separated (e.g., diced) from the wafer and assembled together to form the logic chips 440. After verifying the operable logic chips 440, the processing step 400-d may include bonding the logic chips 440 with the memory chips 405. Thus, the processing step 400-d may form a memory architecture with a relatively greater proportion of operable logic chips 440 than one or more originally formed wafers from which the logic chips 440 were diced. As such, the described examples provide for manufacturing procedures that are based on the bonding of multiple reconstructed wafers, which may increase a manufacturing yield (e.g., of the memory architecture 300).

After forming each logic chip 440, the processing step 400-d may include bonding the logic chips 440 and the memory chips 405. In some cases, the logic chips 440 may be initially positioned above the memory stacks 420, such that a logic chip 440-a may be positioned above the memory stack 420-a and a logic chip 440-b may be positioned above the memory stack 420-b. In some such cases, the logic chips 440 may be aligned with the memory stacks 420 using the alignment features 412 of each logic chip 440 and the corresponding memory chip 405. In some examples, the alignment features 412 may be positioned within the logic chips 440 such that aligning the alignment features 412 along the x-direction and the y-direction may cause the vias 410 of the logic chips 440 and the memory chips 405 to be aligned. For example, aligning the logic chips 440 with the memory stacks 420 may include aligning a via 410-c of the logic chip 440-a with a via 410-a of the memory chip 405-a. In some implementations, aligning the vias 410 of the logic chips 440 and the memory chips 405 may align the bonding pads 415, such that a bonding pad 415 associated with the via 410-c may be aligned with a bonding pad 415 associated with the via 410-a. After aligning the logic chips 440 with the memory stacks 420, the logic chips 440 may be bonded with the memory stacks 420 using hybrid bonding, such that a bonding pad 415 associated with the memory chip 405-a is hybrid bonded with a bonding pad 415 associated with the logic chip 440-a. In some examples, bonding the logic chips 440 with the memory stacks 420 may include bonding front sides (e.g., a top surface) of the logic chips 440 with back sides (e.g., a bottom surface) of the memory chip 405-a. That is, bonding the logic chips 440 with the memory stacks 420 may cause back sides of the logic chips 440 to be exposed as a top surface of the memory architecture.

The processing step 400-d may include forming the dielectric material 435 in voids between the logic chips 440. For example, the processing step 400-d may include depositing the dielectric material 435 above the dielectric material 435 between the memory stacks 420. Further, depositing the dielectric material 435 between the logic chips 440 may surround the logic chips 440 with the dielectric material 435. For example, the dielectric material 435 may be disposed between the logic chip 440-a and the logic chip 440-b. In some examples, the dielectric material 435 may be deposited to a height equivalent to a height of the logic chips 440. In some examples, the processing step 400-d may include planarizing (e.g., remove a top portion, etching a thin layer of the memory architecture) the memory architecture such that the logic chips 440 and the dielectric material 435 are coplanar. In some such examples, planarizing the memory architecture may expose the bonding pads 415 of the logic chips 440.

FIG. 4E illustrates a fifth processing step 400-e for forming a dielectric layer 445 above the logic chips 440. For example, the processing step 400-e may include depositing the dielectric layer 445 above the logic chips 440 and extending throughout the memory architecture in the x-direction. In some cases, the dielectric layer 445 may be a height associated with satisfying a packaging height requirement of the memory architecture. In some cases, the dielectric layer 445 may provide mechanical support for physical translations of the memory architecture during the processing steps 400. The dielectric layer 445 may be a dielectric silicon-based material (e.g., a dummy silicon) including a dielectric portion 447 and a portion 446 for forming redistribution layers 450. In some cases, the portion 446 may include a quantity of dielectric films. The dielectric layer 445 may include the redistribution layers 450, which may be conductive channels (e.g., lines) extending along the x-direction through the dielectric layer 445. The redistribution layers 450 may include bonding pads 415 for bonding with bonding pads 415 of the logic chips 440. The dielectric layer 445 may also include alignment features 412 to support aligning the dielectric layer 445 with the logic chips 440.

In some cases, the processing step 400-e may include bonding the dielectric layer 445 with the logic chips 440. In some such cases, the dielectric layer 445 may be aligned with the logic chips 440 using the alignment features 412 of the dielectric layer 445 and the logic chips 440. In some examples, the alignment features 412 may be positioned within the dielectric layer 445 such that aligning the alignment features 412 along the x-direction and the y-direction may cause the redistribution layers 450 and the vias 410 of the logic chips 440 to be aligned. In some implementations, aligning the redistribution layers 450 and the vias 410 of the logic chips 440 may align the bonding pads 415, such that a bonding pad 415 of the redistribution layers 450 may be aligned with a bonding pad 415 associated with the via 410-c. After aligning the redistribution layers 450 with the logic chips 440, the redistribution layers 450 may be bonded with the logic chips 440 using hybrid bonding, such that a bonding pad 415 associated with the redistribution layers 450 is hybrid bonded with a bonding pad 415 associated with the logic chip 440. In some examples, bonding the dielectric layer 445 with the logic chips 440 may include bonding a front side (e.g., a top surface) of the dielectric layer 445 with back sides (e.g., a bottom surface) of the logic chips 440.

FIG. 4F illustrates a sixth processing step 400-f for forming vias 455. The processing step 400-f may include the vias 455 extending through the dielectric material 435 of the memory architecture. For example, the vias 455 may extend from a bottom of the memory architecture (e.g., a bottom surface of the dielectric material 435) to the redistribution layers 450 along the z-direction. The vias 455 may be through-dielectric vias, which may be conductive channels configured to transfer power to the redistribution layers 450. For example, power may be provided to the vias 455, and the vias 455 may transfer the power to the redistribution layers 450, where the redistribution layers 450 may transfer the power to the logic chips 440, and thereby transfer a portion of the power to the memory stacks 420. In some cases, forming the vias 455 may include removing the sacrificial layer 425 using a planarizing or etching operation. In some such cases, after removing the sacrificial layer 425, the processing step 400-f may include (e.g., flipping the memory architecture along the z-direction and) forming cavities extending from the bottom of the dielectric material 435 to the redistribution layers 450. Then, the processing step 400-f may include filling the cavities with a conductive material (e.g., copper) to form the vias 455.

FIG. 4G and FIG. 4H illustrate a seventh processing step 400-g for forming solder pads 465. The processing step 400-g may include forming a polymer layer 460 below the dielectric material 435. For example, the memory architecture may be flipped along the z-direction and the polymer layer 460 may be deposited on the bottom surface of the dielectric material 435. In some examples, the polymer layer 460 may include a polyimide material. After forming the polymer layer 460, the processing step 400-g may include forming cavities extending through the polymer layer 460 along the z-direction. The cavities may be centered above the vias 410 and the vias 455, such that the cavities may expose bonding pads 415 associated with the vias 410 and a surface of the vias 455. After forming the cavities, the processing step 400-g may include, in some examples, forming a liner in the cavities, where the liner is an aluminum or tungsten material. The processing step 400-g may additionally include forming solder pads 465. For example, after depositing the liner in the cavities, the solder pads 465 may be deposited in the cavities to fill the cavities. In some examples, the solder pads 465 may extend at least partially below the cavities along the z-direction. In some implementations, a layer of solder pad material may be deposited within the cavities and below the cavities along the z-direction, then etched to the polymer layer 460 to form the separate solder pads 465. In some such implementations, the solder pad material may be a copper material. After forming the solder pads 465, the processing step 400-g may include forming solder balls 470 on the solder pads 465. In some cases, the solder balls 470 may be formed by depositing molten solder material on the solder pads 465, where the solder material is a conductive bonding material.

FIG. 4G illustrates the memory architecture from a cross sectional view in an xz-plane where the redistribution layers 450 are coupled between the vias 455 and the vias 410 of the logic chips 440. However, FIG. 4H illustrates the memory architecture from another cross sectional view in another xz-plane at a length away along the y-direction from the xz-plane associated with the FIG. 4G cross sectional view. FIG. 4H illustrates the memory architecture where the redistribution layers 450 are coupled between the vias 410 of adjacent logic chips 440. The vias 455 are not illustrated in FIG. 4H between the adjacent logic chips 440 because the redistribution layers 450 prevent the vias 455 from being implemented between the adjacent logic chips 440 (e.g., to facilitate signaling between the adjacent logic chips 440). In some such cases, the redistribution layers 450 may support relatively high speed signaling between the logic chips 440.

In accordance with examples as described herein, implementing the processing steps 400 for forming the logic chips 440 above the memory stacks 420 may alleviate thermal concentration concerns during power delivery to the memory architecture, by increasing thermal distribution throughout the memory architecture. In some cases, with relatively greater thermal distribution, the memory architecture may experience less degradation, resulting in improved latency of operating the memory architecture. Further, implementing the processing steps 400 for testing the chips prior to forming the memory architecture may ensure defective chips are not implemented in the memory architecture. That is, implementing verified operable components in the memory architecture may further increase reliability of the memory architecture, among other advantages.

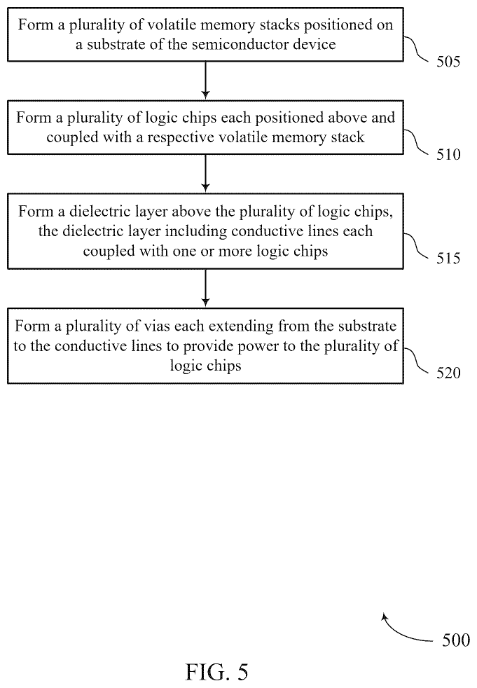

FIG. 5 shows a flowchart illustrating a method or methods 500 that supports backside power delivery to logic of a memory architecture in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of volatile memory stacks positioned on a substrate of the semiconductor device.

At 510, the method may include forming a plurality of logic chips each positioned above and coupled with a respective volatile memory stack.

At 515, the method may include forming a dielectric layer above the plurality of logic chips, the dielectric layer including conductive lines each coupled with one or more logic chips.

At 520, the method may include forming a plurality of vias each extending from the substrate to the conductive lines to provide power to the plurality of logic chips.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a plurality of volatile memory stacks positioned on a substrate of the semiconductor device; forming a plurality of logic chips each positioned above and coupled with a respective volatile memory stack; forming a dielectric layer above the plurality of logic chips, the dielectric layer including conductive lines each coupled with one or more logic chips; and forming a plurality of vias each extending from the substrate to the conductive lines to provide power to the plurality of logic chips.

Aspect 2: The method or apparatus of aspect 1, further including operations, features, circuitry, logic, means, or instructions, or any combination thereof for forming a plurality of solder pads below the substrate, where each via is coupled with a respective solder pad.

Aspect 3: The method or apparatus of aspect 2, where each volatile memory stack includes one or more second vias extending through the respective volatile memory stack and each of the one or more second vias is coupled with a solder pad.

Aspect 4: The method or apparatus of aspect 3, where forming the plurality of solder pads includes operations, features, circuitry, logic, means, or instructions, or any combination thereof for forming the substrate based at least in part on depositing a polymer layer below the plurality of volatile memory stacks; forming a plurality of cavities extending through the polymer layer to the plurality of vias and the one or more second vias; and depositing a conductive material associated with the plurality of solder pads within the plurality of cavities, where the conductive material is coupled with the plurality of vias and the one or more second vias.

Aspect 5: The method or apparatus of any of aspects 3 through 4, where and the method, apparatuses, and non-transitory computer-readable medium includes operations, features, circuitry, logic, means, or instructions, or any combination thereof for where each logic chip is coupled with the respective volatile memory stack based at least in part on the one or more second vias associated with the respective volatile memory stack being coupled with the one or more third vias associated with the logic chip.

Aspect 6: The method or apparatus of any of aspects 1 through 5, where forming a volatile memory stack of the plurality of volatile memory stacks includes operations, features, circuitry, logic, means, or instructions, or any combination thereof for forming a plurality of volatile memory chips; bonding two or more volatile memory chips of the plurality of volatile memory chips; and dicing the two or more volatile memory chips to form the volatile memory stack.

Aspect 7: The method or apparatus of aspect 6, where forming the plurality of volatile memory chips includes operations, features, circuitry, logic, means, or instructions, or any combination thereof for forming a first wafer of volatile memory chips; testing the volatile memory chips to determine whether each volatile memory chip is defective; dicing the first wafer to separate defective volatile memory chips from operable volatile memory chips; and bonding the operable volatile memory chips together into a second wafer, the second wafer including the plurality of volatile memory chips based at least in part on bonding the operable volatile memory chips.

Aspect 8: The method or apparatus of any of aspects 6 through 7, where forming the plurality of volatile memory chips includes operations, features, circuitry, logic, means, or instructions, or any combination thereof for forming one or more second vias extending through each volatile memory chip; where bonding the two or more volatile memory chips includes aligning the two or more volatile memory chips based at least in part on aligning the one or more second vias extending through each of the two or more volatile memory chips.

Aspect 9: The method or apparatus of aspect 8, where the two or more volatile memory chips are coupled based at least in part on coupling the one or more second vias extending through each of the two or more volatile memory chips being coupled.

Aspect 10: The method or apparatus of any of aspects 6 through 9, where bonding the two or more volatile memory chips includes a hybrid bonding operation and dicing the two or more volatile memory chips includes a plasma dicing operation.

Aspect 11: The method or apparatus of any of aspects 6 through 10, where forming the plurality of logic chips includes operations, features, circuitry, logic, means, or instructions, or any combination thereof for forming a first wafer of logic chips; testing the logic chips to determine whether each logic chip is defective; and dicing the first wafer to separate defective logic chips from operable logic chips.

Aspect 12: The method or apparatus of aspect 11, further including operations, features, circuitry, logic, means, or instructions, or any combination thereof for selecting the plurality of logic chips based at least in part on determining each logic chip of the plurality of logic chips is operable and where forming the plurality of logic chips is based at least in part on selecting the plurality of logic chips.

Aspect 13: The method or apparatus of any of aspects 1 through 12, where forming the plurality of volatile memory stacks includes operations, features, circuitry, logic, means, or instructions, or any combination thereof for bonding the plurality of volatile memory stacks with a sacrificial layer; forming a dielectric material between each volatile memory stack; and where forming the plurality of logic chips above the plurality of volatile memory stacks is based at least in part on forming the dielectric material.

Aspect 14: The method or apparatus of aspect 13, where forming the plurality of vias includes operations, features, circuitry, logic, means, or instructions, or any combination thereof for removing the sacrificial layer; forming a plurality of cavities extending through the dielectric material from a bottom surface of the dielectric material to the conductive lines; and depositing a conductive material within the plurality of cavities.

Aspect 15: The method or apparatus of any of aspects 1 through 14, further including operations, features, circuitry, logic, means, or instructions, or any combination thereof for forming a dielectric material between each logic chip and where forming the dielectric layer above the plurality of logic chips is based at least in part on forming the dielectric material.

Aspect 16: The method or apparatus of any of aspects 1 through 15, further including operations, features, circuitry, logic, means, or instructions, or any combination thereof for bonding each logic chip with a respective volatile memory stack.

Aspect 17: The method or apparatus of any of aspects 1 through 16, where each logic chip is coupled with the respective volatile memory stack based at least in part on bonding a front side of the logic chip with a back side of a volatile memory chip within the respective volatile memory stack.

Aspect 18: The method or apparatus of any of aspects 1 through 17, where forming the dielectric layer includes operations, features, circuitry, logic, means, or instructions, or any combination thereof for forming the conductive lines within the dielectric layer, the dielectric layer including a plurality of dielectric films.

Aspect 19: The method or apparatus of aspect 18, where forming the conductive lines within the dielectric layer includes coupling adjacent logic chips of the plurality of logic chips via the conductive lines.

Aspect 20: The method or apparatus of any of aspects 1 through 19, where the dielectric layer includes a silicon based material.

Aspect 21: The method or apparatus of any of aspects 1 through 20, where each logic chip includes a graphics processing unit.

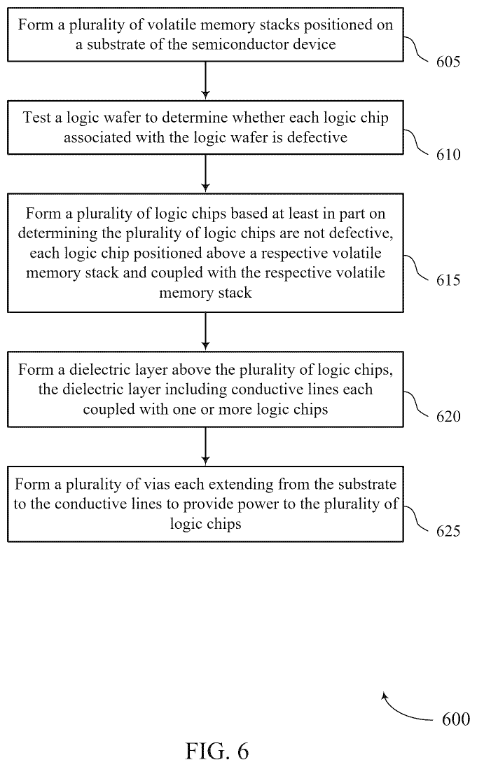

FIG. 6 shows a flowchart illustrating a method 600 that supports backside power delivery to logic of a memory architecture in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a plurality of volatile memory stacks positioned on a substrate of the semiconductor device.

At 610, the method may include testing a logic wafer to determine whether each logic chip associated with the logic wafer is defective.

At 615, the method may include forming a plurality of logic chips based at least in part on determining the plurality of logic chips are not defective, each logic chip positioned above a respective volatile memory stack and coupled with the respective volatile memory stack.

At 620, the method may include forming a dielectric layer above the plurality of logic chips, the dielectric layer including conductive lines each coupled with one or more logic chips.

At 625, the method may include forming a plurality of vias each extending from the substrate to the conductive lines to provide power to the plurality of logic chips.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 22: A method or apparatus including operations, features, circuitry, logic, means, or instructions, or any combination thereof for forming a plurality of volatile memory stacks positioned on a substrate of the semiconductor device; testing a logic wafer to determine whether each logic chip associated with the logic wafer is defective; forming a plurality of logic chips based at least in part on determining the plurality of logic chips are not defective, each logic chip positioned above a respective volatile memory stack and coupled with the respective volatile memory stack; forming a dielectric layer above the plurality of logic chips, the dielectric layer including conductive lines each coupled with one or more logic chips; and forming a plurality of vias each extending from the substrate to the conductive lines to provide power to the plurality of logic chips.

Aspect 23: The method or apparatus of aspect 22, further including operations, features, circuitry, logic, means, or instructions, or any combination thereof for testing a plurality of volatile memory chips to determine whether each volatile memory chip is defective; selecting a subset of volatile memory chips based at least in part on determining each volatile memory chip of the subset of volatile memory chips is not defective; and where forming the plurality of volatile memory stacks is based at least in part on selecting the subset of volatile memory chips and bonding one or more volatile memory chips of the subset of volatile memory chips to form each volatile memory stack.

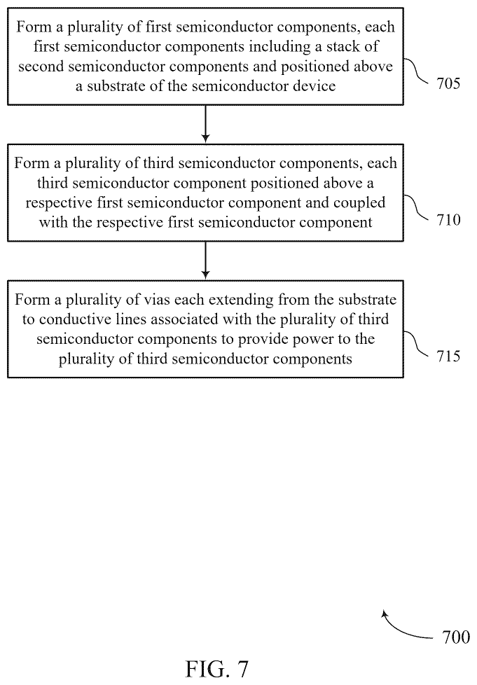

FIG. 7 shows a flowchart illustrating a method 700 that supports backside power delivery to logic of a memory architecture in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include forming a plurality of first semiconductor components, each first semiconductor components including a stack of second semiconductor components and positioned above a substrate of the semiconductor device.

At 710, the method may include forming a plurality of third semiconductor components, each third semiconductor component positioned above a respective first semiconductor component and coupled with the respective first semiconductor component.

At 715, the method may include forming a plurality of vias each extending from the substrate to conductive lines associated with the plurality of third semiconductor components to provide power to the plurality of third semiconductor components.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 24: A method or apparatus including operations, features, circuitry, logic, means, or instructions, or any combination thereof for forming a plurality of first semiconductor components, each first semiconductor components including a stack of second semiconductor components and positioned above a substrate of the semiconductor device; forming a plurality of third semiconductor components, each third semiconductor component positioned above a respective first semiconductor component and coupled with the respective first semiconductor component; and forming a plurality of vias each extending from the substrate to conductive lines associated with the plurality of third semiconductor components to provide power to the plurality of third semiconductor components.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 25: A semiconductor device, including: a plurality of volatile memory stacks positioned above a substrate of the semiconductor device; a plurality of logic chips each above and coupled with a respective volatile memory stack; a dielectric layer above the plurality of logic chips, the dielectric layer including conductive lines each coupled with one or more logic chips; and a plurality of vias each extending from the substrate to the conductive lines to provide power to the plurality of logic chips.

Aspect 26: The semiconductor device of aspect 25, where each volatile memory stack includes one or more volatile memory chips, each volatile memory chip including one or more second vias, each of the one or more volatile memory chips are coupled based at least in part on the one or more second vias.

Aspect 27: The semiconductor device of any of aspects 25 through 26, further including: a plurality of solder pads below the substrate, where each via is coupled with a respective solder pad.

Aspect 28: The semiconductor device of aspect 27, where each volatile memory stack includes one or more second vias extending through the volatile memory stack, and each of the one or more second vias is coupled with a respective solder pad.

Aspect 29: The semiconductor device of aspect 28, where each logic chip includes one or more third vias extending through the respective logic chip, and. where each logic chip is coupled with the respective volatile memory stack based at least in part on the one or more second vias associated with the respective volatile memory stack being coupled with the one or more third vias associated with the logic chip

Aspect 30: The semiconductor device of any of aspects 25 through 29, further including: a dielectric material positioned between each volatile memory stack, and between each logic chip.

Aspect 31: The semiconductor device of any of aspects 25 through 30, where each logic chip is coupled with the respective volatile memory stack based at least in part on bonding a front side of the logic chip with a back side of a volatile memory chip within the respective volatile memory stack.

Aspect 32: The semiconductor device of any of aspects 25 through 31, where the dielectric layer includes a silicon based material.

Aspect 33: The semiconductor device of any of aspects 25 through 32, where each logic chip includes a graphics processing unit.

An apparatus is described. The following provides an overview of aspects of the apparatus as described herein:

Aspect 34: A semiconductor device, including: a stack of volatile memory chips including one or more coupled volatile memory chips positioned above a substrate of the semiconductor device; a logic chip positioned above the stack of volatile memory chips and coupled with the stack of volatile memory chips; a dielectric layer positioned above the logic chip and including one or more conductive lines each coupled with the logic chip; and one or more vias each extending from the substrate of the semiconductor device to the one or more conductive lines.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a semiconductor device, comprising:
forming a plurality of memory stacks positioned on a substrate of the semiconductor device;
forming a plurality of logic chips each positioned above and coupled with a respective memory stack;
forming a dielectric layer above the plurality of logic chips, the dielectric layer comprising conductive lines each coupled with one or more logic chips; and
forming a plurality of vias each extending from the substrate to the conductive lines to provide power to the plurality of logic chips.

2. The method of claim 1, further comprising:
forming a plurality of solder pads below the substrate, wherein each via is coupled with a respective solder pad.

3. The method of claim 2, wherein:
each memory stack comprises one or more second vias extending through the respective memory stack, and
each of the one or more second vias is coupled with a solder pad.

4. The method of claim 3, wherein forming the plurality of solder pads comprises:
forming the substrate based at least in part on depositing a polymer layer below the plurality of memory stacks;
forming a plurality of cavities extending through the polymer layer to the plurality of vias and the one or more second vias; and
depositing a conductive material associated with the plurality of solder pads within the plurality of cavities, wherein the conductive material is coupled with the plurality of vias and the one or more second vias.

5. The method of claim 3, wherein each logic chip comprises one or more third vias extending through the respective logic chip, and
wherein each logic chip is coupled with the respective memory stack based at least in part on the one or more second vias associated with the respective memory stack being coupled with the one or more third vias associated with the logic chip.

6. The method of claim 1, wherein forming a memory stack of the plurality of memory stacks comprises:
forming a plurality of volatile memory chips;
bonding two or more volatile memory chips of the plurality of volatile memory chips; and
dicing the two or more volatile memory chips to form the memory stack.

7. The method of claim 6, wherein forming the plurality of volatile memory chips comprises:
forming a first wafer of volatile memory chips;
testing the volatile memory chips to determine whether each volatile memory chip is defective;
dicing the first wafer to separate defective volatile memory chips from operable volatile memory chips; and
bonding the operable volatile memory chips together into a second wafer, the second wafer comprising the plurality of volatile memory chips based at least in part on bonding the operable volatile memory chips.

8. The method of claim 6, wherein forming the plurality of volatile memory chips comprises:
forming one or more second vias extending through each volatile memory chip,
wherein bonding the two or more volatile memory chips comprises:
aligning the two or more volatile memory chips based at least in part on aligning the one or more second vias extending through each of the two or more volatile memory chips.

9. The method of claim 8, wherein the two or more volatile memory chips are coupled based at least in part on coupling the one or more second vias extending through each of the two or more volatile memory chips being coupled.

10. The method of claim 6, wherein:
bonding the two or more volatile memory chips comprises a hybrid bonding operation.

11. The method of claim 6, wherein forming the plurality of logic chips comprises:
forming a first wafer of logic chips;
testing the logic chips to determine whether each logic chip is defective; and
dicing the first wafer to separate defective logic chips from operable logic chips.

12. The method of claim 11, further comprising:
selecting the plurality of logic chips based at least in part on determining each logic chip of the plurality of logic chips is operable,
wherein forming the plurality of logic chips is based at least in part on selecting the plurality of logic chips.

13. The method of claim 1, wherein forming the plurality of memory stacks comprises:
bonding the plurality of memory stacks with a sacrificial layer; and
forming a dielectric material between each memory stack,
wherein forming the plurality of logic chips above the plurality of memory stacks is based at least in part on forming the dielectric material.

14. The method of claim 13, wherein forming the plurality of vias comprises:
removing the sacrificial layer;
forming a plurality of cavities extending through the dielectric material from a bottom surface of the dielectric material to the conductive lines; and
depositing a conductive material within the plurality of cavities.

15. The method of claim 1, further comprising:
forming a dielectric material between each logic chip,
wherein forming the dielectric layer above the plurality of logic chips is based at least in part on forming the dielectric material.

16. The method of claim 1, further comprising:
bonding each logic chip with a respective memory stack.

17. The method of claim 1, wherein each logic chip is coupled with the respective memory stack based at least in part on bonding a front side of the logic chip with a back side of a volatile memory chip within the respective memory stack.

18. The method of claim 1, wherein forming the dielectric layer comprises:
forming the conductive lines within the dielectric layer, the dielectric layer comprising a plurality of dielectric films.

19. The method of claim 18, wherein forming the conductive lines with the dielectric layer comprises coupling adjacent logic chips of the plurality of logic chips via the conductive lines.

20. The method of claim 1, wherein the dielectric layer comprises a silicon based material.

21. The method of claim 1, wherein each logic chip comprises a graphics processing unit.

22. A semiconductor device, comprising:
a plurality of memory stacks positioned above a substrate of the semiconductor device;
a plurality of logic chips each above and coupled with a respective memory stack;
a dielectric layer above the plurality of logic chips, the dielectric layer comprising conductive lines each coupled with one or more logic chips; and
a plurality of vias each extending from the substrate to the conductive lines to provide power to the plurality of logic chips.

23. The semiconductor device of claim 22, wherein:
each memory stack comprises one or more volatile memory chips, each volatile memory chip comprising one or more second vias,
each of the one or more volatile memory chips are coupled based at least in part on the one or more second vias.

24. The semiconductor device of claim 22, further comprising:
a plurality of solder pads below the substrate, wherein each via is coupled with a respective solder pad.

25. The semiconductor device of claim 24, wherein each memory stack comprises one or more second vias extending through the memory stack, and each of the one or more second vias is coupled with a respective solder pad.

26. The semiconductor device of claim 25, wherein each logic chip comprises one or more third vias extending through the respective logic chip, and
wherein each logic chip is coupled with the respective memory stack based at least in part on the one or more second vias associated with the respective memory stack being coupled with the one or more third vias associated with the logic chip.

27. The semiconductor device of claim 22, further comprising:
a dielectric material positioned between each memory stack, and between each logic chip.

28. The semiconductor device of claim 22, wherein each logic chip is coupled with the respective memory stack based at least in part on bonding a front side of the logic chip with a back side of a volatile memory chip within the respective memory stack.

29. The semiconductor device of claim 22, wherein the dielectric layer comprises a silicon based material.

30. A semiconductor device, comprising:
a stack of volatile memory chips comprising one or more coupled volatile memory chips positioned above a substrate of the semiconductor device;
a logic chip positioned above the stack of volatile memory chips and coupled with the stack of volatile memory chips;
a dielectric layer positioned above the logic chip and comprising one or more conductive lines each coupled with the logic chip; and
one or more vias each extending from the substrate of the semiconductor device to the one or more conductive lines.
